(19) United States
(12) Patent Application Publication
(10) Pub. No.: US 2025/0330125 A1
(43) Pub. Date: Oct. 23, 2025

(54) HIGH-VOLTAGE INPUT STAGE CIRCUIT WITHOUT BIAS CURRENT

(71) Applicant: SG MICRO CORP, Beijing (CN)

(72) Inventor: Lidi ZHANG, Beijing (CN)

(73) Assignee: SG MICRO CORP, Beijing (CN)

(21) Appl. No.: 18/855,719

(22) PCT Filed: Apr. 11, 2023
(86) PCT No.: PCT/CN2023/087556

§ 371 Date: Oct. 10, 2024

(30) Foreign Application Priority Data
Apr. 12, 2022 (CN) 202210379967.X

(51) Int. Cl. H03F 1/02; H03F 3/45

(52) U.S. Cl. CPC H03F 1/0216; H03F 3/45179; H03F 2200/426

(57) ABSTRACT

A high-voltage input stage circuit without bias current includes a high-voltage conversion unit, a clamping unit and an input unit. The high-voltage conversion unit is connected to the clamping unit, and is used to generate a unique switching voltage based on the magnitude of the differential input voltage, and the switching voltage is respectively input into the positive phase clamping unit and the negative phase clamping unit of the clamping unit. The clamping unit is connected to the high-voltage conversion unit and the input unit, and is used to realize conduction or shutdown based on the switching voltage to input the differential input voltage into the input unit; the input unit is used to realize voltage output to the subsequent load.

### RELATED APPLICATIONS

The present patent application document claims the benefit of priority to CN Patent Application No. 20/221,0379967.X, filed Apr. 12, 2022, and entitled “High voltage input stage circuit without bias currents” the entire contents of which are incorporated herein by reference.

### FIELD

The present disclosure relates to the field of integrated circuits, and more particularly to a high-voltage input stage circuit without bias current.

### BACKGROUND

At present, operational amplifiers or comparators can usually only be used in chips with lower voltages. If the power supply voltage is high and the input voltage required by the load circuit is high, some operational amplifiers or comparators are difficult to use. This is because when the differential voltage of the operational amplifier or comparator is too large and close to the high-voltage power supply voltage, the gate-source voltage of the MOS tube at the input stage is too large, resulting in damage.

In order to solve the above problems, the prior art generally uses a transistor to form a positive and negative clamp circuit to clamp the input pair of an operational amplifier or a comparator. This method can ensure that the differential voltage of the input pair is clamped below twice the base-emitter voltage difference of the transistor. Although this method improves the safety range of the input pair differential voltage to a certain extent, when the differential voltage exceeds twice the base-emitter voltage difference of the transistor, the two input pairs will be turned on, which will also cause the risk of device damage.

On the other hand, in order to prevent the input pair of the comparator or op amp from being greatly misaligned and to operate in a normal state, a large bias current will exist at the input end when the differential voltage is large. For high-voltage input pairs with large differential voltages, the bias current is also difficult to adjust and accurately control, which deteriorates the “virtual disconnection” characteristics of the op amp or comparator and reduces the differential input impedance.

In view of the above problems, the present disclosure provides a high voltage input stage circuit and method without bias current.

### SUMMARY

In order to solve the deficiencies in the existing technologies, the purpose of the present disclosure is to provide a high-voltage input stage circuit without bias current, which generates a switching voltage through a high-voltage conversion unit and controls the on or off state of a clamping unit, thereby realizing the output of an input pair.

The present disclosure adopts the following technical solution.

The first aspect of the present invention relates to a high-voltage input stage circuit without bias current, wherein the circuit includes a high-voltage conversion unit, a clamping unit and an input unit; the high-voltage conversion unit connects to the clamping unit and generates a unique switching voltage based on the size of the differential input voltage, and inputs the switching voltage into the positive phase clamping unit and the negative phase clamping unit of the clamping unit respectively; the clamping unit connects to the high-voltage conversion unit and the input unit and is used to realize conduction or shutdown based on the switching voltage so as to input the differential input voltage into the input unit; the input unit is used to realize voltage output to the subsequent load.

Optionally, the high-voltage conversion unit includes a bias current source, a positive phase bias branch and a negative phase bias branch; wherein the positive phase bias branch and the negative phase bias branch respectively connect to the bias current source, and the bias current is distributed between the positive phase bias branch and the negative phase bias branch based on the differential input voltage.

Optionally, the positive phase bias branch includes a first bias tube Mp3, a second bias tube Mp5, and a bias Zener tube D5; wherein, the source of the first bias tube Mp3 and the source of the second bias tube Mp5 are interconnected and connect to the negative end of the bias Zener tube D5; the gate of the first bias tube Mp3 and the gate of the second bias tube Mp5 are interconnected and connect to the positive end of the bias Zener tube D5 and the positive phase input voltage IN+; the drain of the first bias tube Mp3 is grounded, and the drain of the second bias tube Mp5 connects to the bias current source It1 through the switching voltage control tube Mn1; the circuit structure of the negative phase bias branch is the same as that of the positive phase bias branch.

Optionally, one end of the bias current source connects to the power supply voltage, and the other end connects to the drain and gate of the switch voltage control tube Mn1; the source of the switch voltage control tube Mn1 connects to the positive phase bias branch and the negative phase bias branch respectively.

Optionally, the positive phase clamping unit has the same circuit structure as the negative phase clamping unit; wherein, the positive phase clamping unit includes a switch tube Mnsw1 and a clamping Zener diode D1; the drain of the switch tube Mnsw1 connects to the positive phase input voltage IN+, the gate respectively connects to the switch voltage and the negative end of the clamping Zener diode D1, and the source connects to the positive end of the clamping Zener diode D1 and the gate of the positive phase input tube Mp1 in the input unit.

Optionally, the differential input voltage is the difference between the positive input voltage IN+ and the negative input voltage IN−; and when the differential input voltage causes the positive bias branch and the negative bias branch to be turned on at the same time, the switching voltage is the sum of the drain-source voltage difference of the switching voltage control tube and the source-gate voltage difference of the first bias tube in the positive bias branch or the negative bias branch.

Optionally, when the differential input voltage causes one of the positive phase bias branch or the negative phase bias branch to be cut off, the switching voltage is the sum of the drain-source voltage difference of the switching voltage control tube and the source-gate voltage difference of all bias tubes in the positive phase bias branch or the negative phase bias branch that are in the on state.

Optionally, when the positive input voltage IN+ or the negative input voltage IN− is greater than the difference between the switch voltage and the threshold turn-on voltage of the switch tube, the switch tube in the clamping unit receiving the positive input voltage IN+ or the negative input voltage IN− is in a cut-off state.

Optionally, the threshold opening voltage of the switch voltage control tube Mn1 and the threshold opening voltage of the switch tubes Mnsw1 and Mnsw2 in the clamping unit are equal.

Optionally, the width-to-length ratios of the bias tubes Mp3, Mp4, Mp5 and Mp6 are equal.

Optionally, the reverse conduction voltage of the Zener diode is equal to the maximum gate-source voltage difference of the positive phase input tube Mp1, the negative phase input tube Mp2, the switch tube Mnsw1, the switch tube Mnsw2 and the bias tubes Mp3, Mp4, Mp5 and Mp6.

The beneficial effect of the present invention is that, compared with the prior art, the high-voltage input stage circuit without bias current in the present invention generates a switch voltage through a high-voltage conversion unit and controls the on or off state of the clamping unit, thereby realizing the output of the input pair. The circuit of the present invention can be applied to high-voltage power supplies and high-input differential voltage chips with a large voltage range, and will not cause device damage. Even in a high-input differential voltage environment, it can still maintain the absence of bias current at the input end, so that the differential input impedance is very high, and the “virtual disconnection” characteristics of the operational amplifier or comparator are ensured.

### BRIEF DESCRIPTION OF THE DRAWINGS

FIG. 1 is an input stage circuit in the existing technologies of the present disclosure;

FIG. 2 is a high-voltage input stage circuit in the existing technologies of the present disclosure;

FIG. 3 is a circuit structure diagram of a high-voltage conversion unit in a high-voltage input stage circuit without bias current in the present disclosure;

FIG. 4 is a circuit structure diagram of a clamping unit and an input unit in a high-voltage input stage circuit without bias current in the present disclosure.

### DETAILED DESCRIPTION

The present application is further described below in conjunction with the accompanying drawings. The following embodiments are only used to more clearly illustrate the technical solution of the present invention, and cannot be used to limit the protection scope of the present application.

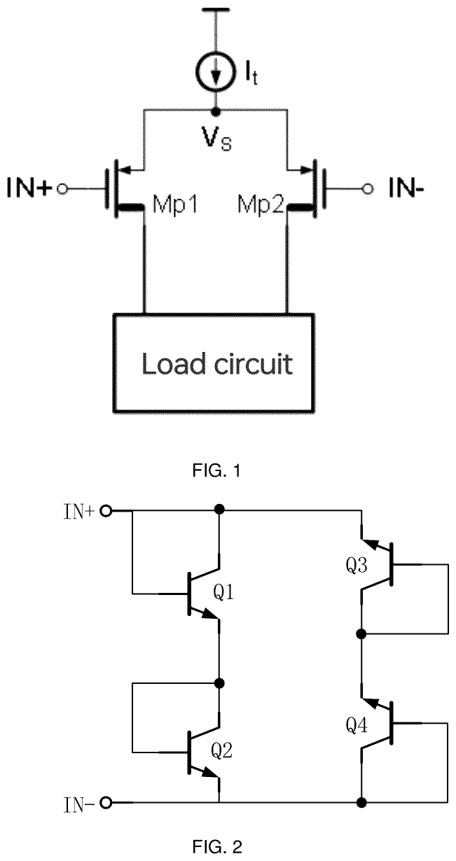

FIG. 1 is an input stage circuit in the existing technologies of the present disclosure. As shown in FIG. 1, the input stage of a general operational amplifier or comparator includes two MOS tubes, the source of the MOS tubes is connected to a current source, the gate is respectively connected to a differential voltage pair, and the drain is used as an output to provide a voltage difference for a subsequent load circuit.

However, this circuit is usually only applicable to chips with high power supply voltage and low input differential voltage. When the input differential voltage of the chip is high, this input stage circuit will be broken down by the high differential voltage, causing damage to the entire chip.

FIG. 2 is a high-voltage input stage circuit in the existing technologies of the present disclosure. As shown in FIG. 2, the present disclosure can use a positive and negative clamping circuit formed by a transistor to improve the application scope of the input stage circuit. Generally speaking, two transistors Q1 and Q3 form a positive and negative clamping structure, in which the base and collector of Q1 are connected to the emitter of Q3, and the emitter of Q1 is connected to the base and collector of Q2 at the inverting input terminal, and the collector and base of Q3 are connected to the emitter of Q4 at the inverting input terminal. Through this positive and negative clamping method, when the driving capability of IN+ and IN− is weak, no matter which voltage of IN+ and IN− is higher, it can be ensured that the voltage difference between IN+ and IN− does not exceed 2 times the Vbe voltage difference. Wherein Vbe is the voltage difference between the base emitters of the four transistors.

However, in this circuit, if the voltage difference between IN+ and IN− is greater than 2 times Vbe, the transistor branch may be turned on. At this time, as the voltage difference increases, if the driving capabilities of IN+ and IN− are strong, a large current will flow through the branch where Q1 and Q2 are located or the branch where Q3 and Q4 are located, causing damage to the device.

In order to solve the above problems, the present disclosure provides an input stage circuit that can be used in a high power supply voltage and high input differential voltage chip environment. The circuit is designed based on LDMOS (Laterally Diffused Metal Oxide Semiconductor) to design the high voltage input stage circuit described below.

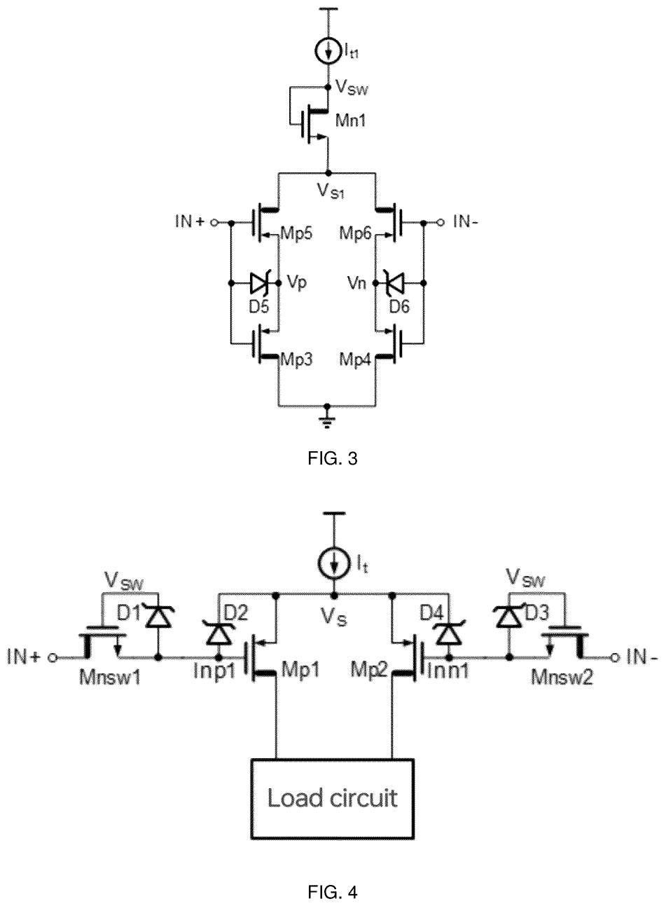

FIG. 3 is a schematic diagram of the circuit structure of a high-voltage conversion unit in a high-voltage input stage circuit without bias current in the present disclosure. FIG. 4 is a schematic diagram of the circuit structure of a clamping unit and an input unit in a high-voltage input stage circuit without bias current in the present invention. As shown in FIG. 3 and FIG. 4, a high-voltage input stage circuit without bias current includes a high-voltage conversion unit, a clamping unit and an input unit; wherein the high-voltage conversion unit is connected to the clamping unit, and is used to generate a unique switching voltage based on the magnitude of the differential input voltage, and input the switching voltage to the positive phase clamping unit and the negative phase clamping unit of the clamping unit respectively; the clamping unit is connected to the high-voltage conversion unit and the input unit, and is used to realize conduction or shutdown based on the switching voltage to input the differential input voltage into the input unit; the input unit is used to realize voltage output to the subsequent load.

It can be understood that in the present disclosure, the high-voltage conversion unit can simultaneously convert the positive-phase input voltage and the negative-phase input voltage with a larger voltage value range into a switching voltage and output it to the clamping unit to realize the output of the input voltage to the input pair.

Preferably, the high-voltage conversion unit includes a bias current source, a positive phase bias branch and a negative phase bias branch; wherein the positive phase bias branch and the negative phase bias branch are respectively connected to the bias current source, and the bias current is distributed between the positive phase bias branch and the negative phase bias branch based on the differential input voltage.

It can be understood that the function of the high voltage conversion unit in the present disclosure is to realize the generation of the switching voltage according to the input of the positive phase input voltage and the negative phase input voltage.

Optionally, the positive phase bias branch includes a first bias tube Mp3, a second bias tube Mp5, and a bias Zener tube D5; wherein, the source of the first bias tube Mp3 and the source of the second bias tube Mp5 are interconnected and connected to the negative end of the bias Zener tube D5; the gate of the first bias tube Mp3 and the gate of the second bias tube Mp5 are interconnected and connected to the positive end of the bias Zener tube D5 and the positive phase input voltage IN+; the drain of the first bias tube Mp3 is grounded, and the drain of the second bias tube Mp5 is connected to the bias current source It1 through the switching voltage control tube Mn1; the circuit structure of the negative phase bias branch is the same as that of the positive phase bias branch.

Optionally, one end of the bias current source is connected to the power supply voltage, and the other end is connected to the drain and gate of the switch voltage control tube Mn1; the source of the switch voltage control tube Mn1 is connected to the positive phase bias branch and the negative phase bias branch respectively.

Specifically, in the positive phase bias branch, there are two bias tubes Mp3 and Mp5, and in the negative phase bias branch, there are another two bias tubes Mp4 and Mp6. When the positive phase input voltage and the negative phase input voltage in the circuit are equal, the differential voltage is 0V. In this case, the voltage at the Vₚ point in the circuit should be Vₚ=IN₊+V_{sg-Mp3}. Among them, IN₊ is the gate voltage of the Mp3 tube, and V_{sg-Mp3} is the source-gate voltage difference of the Mp3 tube. Since the voltage of Vₚ is higher than IN₊, Mp5 enters the linear region, the source-drain resistance is small, and the voltage drop is basically 0V. At this time, it can be obtained that the voltage of V_{S1} is basically equal to the voltage of Vₚ. Similarly, for the negative phase bias branch, Vₙ=IN₋+V_{sg-Mp4}, which is also basically equal to V_{S1}.

Furthermore, according to the connection method of Mn1 tube, the voltage of the drain of Mn1 tube is the sum of V_{S1} and the gate-source voltage difference of Mn1 tube, so V_{SW}=IN₋+V_{sg-Mp4}+V_{gs-Mn1}=IN₊+V_{sg-Mp3}+V_{gs-Mn1}.

Preferably, the differential input voltage is the difference between the positive input voltage IN+ and the negative input voltage IN−; and when the differential input voltage causes the positive bias branch and the negative bias branch to be turned on at the same time, the switching voltage is the sum of the drain-source voltage difference of the switching voltage control tube and the source-gate voltage difference of the first bias tube in the positive bias branch or the negative bias branch.

Preferably, when the differential input voltage causes one of the positive phase bias branch or the negative phase bias branch to be cut off, the switching voltage is the sum of the drain-source voltage difference of the switching voltage control tube and the source-gate voltage difference of the first bias tube in the positive phase bias branch or the negative phase bias branch in the on state.

It can be understood that when the magnitudes of IN+ and IN− are the same or similar, the two bias branches are turned on at the same time, and the switch voltage can be directly determined according to the above formula.

When the magnitudes of IN+ and IN− differ greatly, that is, the differential voltage is large, one of the branches will be in the cut-off state, so the switch voltage can only be determined according to the voltage state of one of the conducting branches.

Preferably, the positive phase clamping unit has the same circuit structure as the negative phase clamping unit; wherein the positive phase clamping unit comprises a switch tube Mnsw1 and a clamping Zener diode D1; the drain of the switch tube Mnsw1 is connected to the positive phase input voltage IN+, the gate is respectively connected to the switch voltage and the negative end of the clamping Zener diode D1, and the source is connected to the positive end of the clamping Zener diode D1 and the gate of the positive phase input tube Mp1 in the input unit.

It is understandable that the main components of the clamping unit in the present invention are the switch tubes Mnsw1 and Mnsw2. The clamping Zener diode is mainly used to ensure that Mnsw1 and Mnsw2 will not be broken down. The reverse conduction voltage of the Zener diode can be set to 5.5V corresponding to the gate-source voltage characteristic of the MOS tube.

Preferably, the reverse conduction voltage of the Zener diode is equal to the maximum gate-source voltage difference of the positive phase input tube Mp1, the negative phase input tube Mp2, the switch tube Mnsw1, the switch tube Mnsw2 and the bias tubes Mp3, Mp4, Mp5 and Mp6.

Similarly, the other diodes D2, D3, D4, D5 and D6 in the present disclosure are all Zener diodes, and their functions are similar to those of the clamping Zener diode D1, and they can clamp the gate-source voltage of the MOS tube connected to them. Therefore, the reverse conduction voltage of the Zener diode in the present disclosure can be set according to the gate-source voltage characteristics of each MOS tube.

Preferably, when the positive input voltage IN+ or the negative input voltage IN− is greater than the difference between the switch voltage and the threshold turn-on voltage of the switch tube, the switch tube in the clamping unit receiving the positive input voltage IN+ or the negative input voltage IN− is in a cut-off state.

Specifically, when the difference between IN+ and IN− is small, according to the magnitude of the switch voltage obtained in the above solution, it can be known that the gate voltage of the Mnsw1 tube is greater than its drain voltage. At this time, the source-drain flip of the Mnsw1 tube will occur, so that Mnsw1 is turned on, so that IN+ is output to the gate of the Mp1 tube. Mnsw2 is also turned on in a similar way, so that IN− is output to the gate of the Mp2 tube.

However, when the difference between IN+ and IN− is large, there will be a situation where one branch in the high-voltage conversion unit is not turned on. For example, in the extreme case where the power supply voltage is 40V and the differential voltage is also 40V, if IN+ is large, the positive phase bias branch will not be turned on, and the switch voltage V_{SW}=IN⁻+V_{sg-Mp4}+V_{gs-Mn1} at this time. Even so, for Mnsw1, since IN+ is too large, the source and drain voltages of Mnsw1 are both greater than the difference between its gate voltage and the threshold turn-on voltage. At this time, Mnsw1 cannot be turned on, and IN+ cannot be connected to the input unit, protecting the input unit from being damaged by the high input differential voltage. On the other hand, since IN− is small, Mnsw2 can still be turned on, so IN− can be connected to the input unit, and the reverse bias voltage of Zener diode D3 is V_{SW}−IN₋=V_{sg-Mp4}+V_{gs-Mn1}, which is much smaller than the reverse breakdown voltage of 5.5V, so there is no reverse current in diode D3. For the input unit, Mp1 is cut off, Mp2 is turned on, and the reverse bias voltage of Zener diode D4 is V_{S}−IN₋=V_{sg-Mp2}, which is much smaller than the reverse breakdown voltage of 5.5V, so there is no reverse current in diode D4.

In summary, there is no bias current at both the IN+ and IN− input terminals.

Similarly, if IN+ is smaller and IN− is larger, Mnsw1 is turned on and Mnsw2 is turned off. At this time, there is no bias current at both IN+ and IN− input terminals. Therefore, in a high input differential voltage environment, there is still no bias current at the input terminal, making the differential input impedance very high.

Optionally, the threshold opening voltage of the switch voltage control tube Mn1 and the threshold opening voltage of the switch tubes Mnsw1 and Mnsw2 in the clamping unit are equal.

Specifically, when the threshold turn-on voltage of the switch voltage control tube Mn1 and the threshold turn-on voltage of the switch tube in the clamping unit are equal, V_{SW}=IN₋+V_{sg-Mp4}+V_{gs-Mn1}=IN₋+V_{sg-Mp4}+Vₜₕ can be obtained. Among them, Vₜₕ is the threshold turn-on voltage of the switch tube.

Specifically, the critical switching point of Mnsw1 and Mnsw2 is V_{SW}−Vₜₕ=IN₊ or IN₋, that is, when the positive phase input voltage IN₊=V_{SW-Vth}=IN₋+V_{sg-Mp4}, Mnsw1 is in a critical state, and when IN₊>IN₋+V_{sg-Mp4}, that is, when the differential voltage is greater than V_{sg-Mp4}, the tube is cut off. Similarly, the critical state of Mnsw2 is IN₋=V_{SW}−Vₜₕ=IN₊+V_{sg-Mp3}, that is, when the differential voltage is greater than V_{sg-Mp3}, the tube is cut off.

Preferably, the width-to-length ratios of the bias tubes Mp3, Mp4, Mp5 and Mp6 are equal. Specifically, ensuring that the width-to-length ratios of the four bias tubes are equal can make circuit design easier and the differential voltage pair is completely symmetrical.

The beneficial effect of the present disclosure is that, compared with the existing technologies, a high-voltage input stage circuit without bias current in the present disclosure generates a switching voltage through a high-voltage conversion unit and controls the on or off state of the clamping unit, thereby realizing the output of the input pair. The circuit of the present disclosure can be applied to high-voltage power supplies and high-input differential voltage chips with a large voltage range, and will not cause device damage. Even in a high-input differential voltage environment, it can still maintain the absence of bias current at the input end, so that the differential input impedance is very high, ensuring the “virtual disconnection” characteristics of the operational amplifier or comparator. The applicant of the present disclosure has made a detailed explanation and description of the implementation examples of the present disclosure in conjunction with the drawings of the specification, but those skilled in the art should understand that the above implementation examples are only preferred implementation schemes of the present disclosure, and the detailed description is only to help readers better understand the spirit of the present disclosure, and it is not a limitation on the protection scope of the present disclosure. On the contrary, any improvement or modification based on the inventive spirit of the present disclosure should fall within the protection scope of the present disclosure.

1-11. (canceled)

12. A high-voltage input stage circuit without bias current, comprising:
a high-voltage conversion unit, a clamping unit and an input unit;
wherein the high-voltage conversion unit connecting to the clamping unit and generating a unique switching voltage based on a magnitude of a differential input voltage, and inputting the switching voltage to a positive phase clamping unit and a negative phase clamping unit of the clamping unit respectively;
the clamping unit connecting the high-voltage conversion unit and the input unit, and realizing conduction or shutdown based on the switching voltage, and to input the differential input voltage into the input unit;
the input unit is used to realize voltage output to the subsequent load.

13. The high-voltage input stage circuit without bias current according to claim 12, further comprising:
the high-voltage conversion unit includes a bias current source, a positive phase bias branch, and a negative phase bias branch;
wherein the positive phase bias branch and the negative phase bias branch are respectively connected to the bias current source, and
the bias current is distributed between the positive phase bias branch and the negative phase bias branch based on the differential input voltage.

14. The high-voltage input stage circuit without bias current according to claim 13, further comprising:
the positive phase bias branch includes a first bias tube Mp3, a second bias tube Mp5, and a bias Zener tube D5; wherein,
the source of the first bias tube Mp3 and the source of the second bias tube Mp5 are interconnected and connecting to the negative end of the bias Zener tube D5;
the gate of the first bias tube Mp3 and the gate of the second bias tube Mp5 are interconnected and connecting to the positive end of the bias Zener tube D5 and the positive phase input voltage IN+;
the drain of the first bias tube Mp3 is grounded, and the drain of the second bias tube Mp5 is connected to the bias current source It1 through the switch voltage control tube Mn1;
the circuit structure of the negative phase bias branch is the same as that of the positive phase bias branch.

15. The high-voltage input stage circuit without bias current according to claim 14, further comprising:
one end of the bias current source connects to the power supply voltage, and the other end connects to the drain and gate of the switch voltage control tube Mn1;
the source of the switch voltage control tube Mn1 connects to the positive phase bias branch and the negative phase bias branch respectively.

16. The high-voltage input stage circuit without bias current according to claim 15, further comprising:
the positive phase clamping unit has the same circuit structure as the negative phase clamping unit; wherein, the positive phase clamping unit includes a switch tube Mnsw1 and a clamping Zener diode D1;
the drain of the switch tube Mnsw1 is connected to the positive phase input voltage IN+, the gate is respectively connected to the switch voltage and the negative end of the clamping Zener diode D1, and the source is connected to the positive end of the clamping Zener diode D1 and the gate of the positive phase input tube Mp1 in the input unit.

17. The high-voltage input stage circuit without bias current according to claim 16, further comprising:
the differential input voltage is the difference between the positive phase input voltage IN+ and the negative phase input voltage IN−; and,
when the differential input voltage causes the positive phase bias branch and the negative phase bias branch to be turned on at the same time,
the switch voltage is the sum of the drain-source voltage difference of the switch voltage control tube and the source-gate voltage difference of the first bias tube in the positive phase bias branch or the negative phase bias branch.

18. The high-voltage input stage circuit without bias current according to claim 17, further comprising:
when the differential input voltage causes one of the positive phase bias branch or the negative phase bias branch to be cut off,
the switching voltage is the sum of the drain-source voltage difference of the switching voltage control tube and the source-gate voltage difference of all bias tubes in the positive phase bias branch or the negative phase bias branch that are in the on state.

19. The high-voltage input stage circuit without bias current according to claim 18, further comprising:
when the positive input voltage IN+ or the negative input voltage IN− is greater than the difference between the switch voltage and the threshold turn-on voltage of the switch tube,
the switch tube in the clamping unit receiving the positive input voltage IN+ or the negative input voltage IN− is in the cut-off state.

20. The high-voltage input stage circuit without bias current according to claim 19, further comprising:
the threshold opening voltage of the switch voltage control tube Mn1 and the threshold opening voltage of the switch tubes Mnsw1 and Mnsw2 in the clamping unit are equal.

21. The high-voltage input stage circuit without bias current according to claim 20, further comprising:
the width-to-length ratios of the bias tubes Mp3, Mp4, Mp5 and Mp6 are equal.

22. The high-voltage input stage circuit without bias current according to claim 21, further comprising:
the reverse conduction voltage of the Zener diode is equal to the maximum gate-source voltage difference of the positive phase input tube Mp1, the negative phase input tube Mp2, the switch tube Mnsw1, the switch tube Mnsw2 and the bias tubes Mp3, Mp4, Mp5 and Mp6.
